(19) United States
(12) Patent Application Publication
(10) Pub. No.: US 2004/0253834 A1
(43) Pub. Date: Dec. 16, 2004

(54) Method for fabricating a trench isolation structure

(75) Inventors: Kerstin Mothes, Dresden (DE); Andreas Klipp, Dresden (DE); Florian Schmitt, Dresden (DE); Mark Hollatz, Neustadt (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 10/812,418

(22) Filed: Mar. 30, 2004

(30) Foreign Application Priority Data
Mar. 31, 2003 (DE) 103 14 574.5

(51) Int. Cl. H01L 21/31

(52) U.S. Cl. 438/778

(57) ABSTRACT

Method for fabricating a trench isolation structure The invention provides a method for fabricating a trench isolation structure, comprising the following steps: forming a mask (3) on a substrate (1); forming at least one trench (2) in the substrate (1) by means of the mask (3); carrying out selective deposition of a first insulation material (5) to at least partially fill the at least one trench (2) in the substrate (1) with the insulation material (5) in the presence of the mask (3); and applying a second insulation material (6) over the entire surface of the structure in order to fill the at least one trench (2) in the substrate (1) at least up to the top side of the mask (3).

### CLAIM FOR PRIORITY

This application claims priority to German Application No. 103 14 574.5, filed Mar. 31, 2003 in the German language, the contents of which are hereby incorporated by reference.

### TECHNICAL FIELD OF THE INVENTION

The present invention relates to a method for fabricating a trench isolation structure (shallow trench isolation, STI), in which by means of a mask at least one trench is fabricated in a substrate and is then filled with an insulating filling material.

### BACKGROUND OF THE INVENTION

Trench isolation structures form lateral insulating structures between adjacent electrically active areas which are formed as trenches which have been etched in a semiconductor substrate and filled with an electrically insulating material. Insulation structures of this type are required since the high packing density of modern integrated circuits (ICs) means that the distances between the active components on the semiconductor wafer are so short that these components influence one another to a considerable extent. This may also give rise to parasitic components which interfere with the functioning of the original components. Trench isolation structures represent possible ways of isolating the adjacent electrically active areas in this context.

Hitherto, trench isolation structures have been fabricated by filling recesses or trenches in substrates by means of an HDP process (High Density HDP process). A process of this type for completely filling STI isolation trenches, an HDP process for the deposition of undoped silicon oxide which is deposited direct from the vapor phase in the trenches of the substrate, is known from S. V. Nguyen, “High-Density Plasma Chemical Vapor Deposition of Silicon-based Dielectric Films for Integrated Circuits”, IBM Journal of Research and Development, Vol. 43, 1/2, 1999.

The increasing miniaturization or the further decrease in feature size, which requires fabrication of trench isolation structures with an increasing aspect ratio of more than 5:1, entails problems.

To explain the technical background, FIG. 4 shows a trench isolation structure which has been fabricated by means of a conventional filling method used in the HDP process. With high aspect ratios of the trenches 2, which result from the decrease in distances between the components on a semiconductor substrate, the operation of filling 5 the isolation trenches 2 has proven increasingly difficult. Internal cavities 7, known as voids, occur in particular with geometric dimensions of this nature (with an aspect ratio of greater than 4:1) as a result of these boundary conditions being used in the fabrication processes. Voids 7 of this nature may be opened up during process steps involved in the fabrication of integrated circuits which follow the fabrication of the trench isolation structure, and materials used in later process steps can then undesirably become lodged in the voids and restrict or prevent the functionality of the circuit on account of short circuits or other physical effects which result. This leads to failures, which makes it much more difficult and expensive to fabricate perfect circuits in mass production.

To prevent the formation of voids 7 of this nature, fillings for the fabrication of trench isolation structures with correspondingly high aspect ratios are fabricated by a plurality of process steps. In this case, a trench 2 is partially filled with material 5 by an HDP process step and is then reduced back to void-free material by being etched back by wet-chemical means. These steps are repeated at least three times, until the trench 2 for fabrication of the trench isolation structure has been filled. This method is highly complex and is also an expensive process.

It is an object of the invention to provide an improved method for the fabrication of a trench isolation structure, in which no voids are formed during the filling of the trenches in the substrate and the need for repeated etchback method steps are avoided in the fabrication of the trench isolation structure.

This object is achieved by a method for fabricating a trench isolation structure as described in claim 1.

### SUMMARY OF THE INVENTION

The invention provides for selective deposition of insulation material to at least partially fill at least one trench which has been formed in a substrate by means of a mask, and then for the application of a further insulation layer, e.g. as an HDP oxide deposition layer, to the substrate structure. The selective preliminary filling of the trenches with a selective insulation material in the presence of the mask prevents the trench from being closed up prematurely through growth of material in the upper region.

According to a preferred refinement, the substrate is made from silicon, the mask is made from silicon nitride and the first and second insulation materials are formed by silicon oxide.

According to a further preferred refinement, after the selected deposition a conditioning step is carried out in order to compact the first insulation material.

According to a further preferred refinement, the application of the second insulation material is carried out by an HDP process (“High Density Plasma” process), preferably in the same process tool.

According to a further preferred refinement, the second insulation material is planarized by chemical mechanical polishing (CMP) on the mask.

### BRIEF DESCRIPTION OF THE DRAWINGS

An embodiment of the invention is explained below with reference to the drawings, in which:

FIG. 1 diagrammatically depicts trenches with a high aspect ratio in a substrate which have been formed by means of a mask;

FIG. 2 shows partial selective preliminary filling of the trenches with an oxide deposition material;

FIG. 3 shows the provision of an HDP oxide deposition layer on the entire structure which has been generated thus far; and

FIG. 4 diagrammatically depicts a trench isolation structure which has been produced by conventional methods, with disruptive voids caused by the process technology which has been employed.

Throughout the figures, identical reference numerals denote identical or functionally equivalent elements.

### DETAILED DESCRIPTION OF THE INVENTION

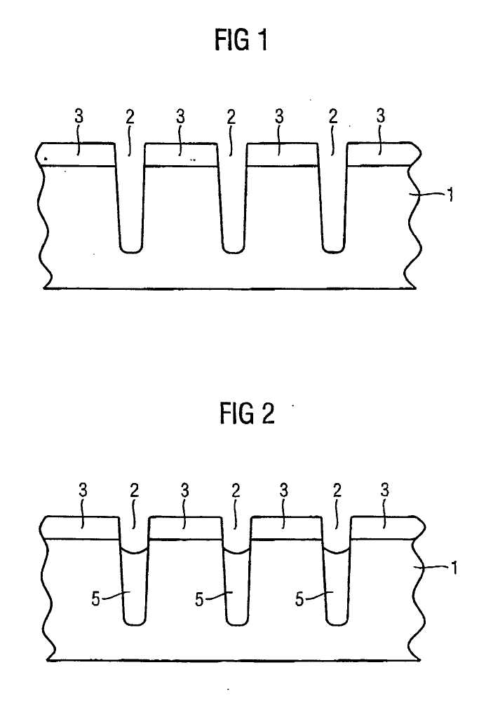

FIG. 1 illustrates a substrate 1 made from silicon, for example, in which trenches 2 have been prepared for preliminary filling with amorphous silicon oxide by means of mask 2, preferably consisting of silicon nitride, so that a trench isolation structure can be fabricated. In this embodiment, the trenches 2 have an aspect ratio, i.e. a ratio of the height of trench to its width, of more than 5:1 (>5,0).

Then, as illustrated in FIG. 2, the trenches 2 are selectively preliminarily filled with an oxide deposition material 5. In this step, the oxide deposition material 5 is grown selectively only in the trenches 2 on the silicon of the substrate 1, but not on the nitride of the mask 3.

An example of a selective oxide deposition process of this type is an ozone TEOS process with a high process pressure and a high ozone content. In this case, scarcely any oxide grows on the nitride mask 3.

In addition to amorphous silicon oxide, it is also possible for the insulation material 5 used to be carbon-containing silicon oxide (low-k material) with a low dielectric constant.

The preliminary filling or partial filling has reduced the aspect ratio to a sufficient extent for it to be possible for further filling at a later stage to be carried out in just one operation in the same process tool.

According to one exemplary embodiment of the present invention, the selective oxide deposition can be followed by oxide deposition in the active areas (referred to as “AA oxide deposition”). This results in the formation of an AA oxide (not shown) for edge rounding and in compacting of the selective oxide 5 which has previously been deposited in the trenches 2.

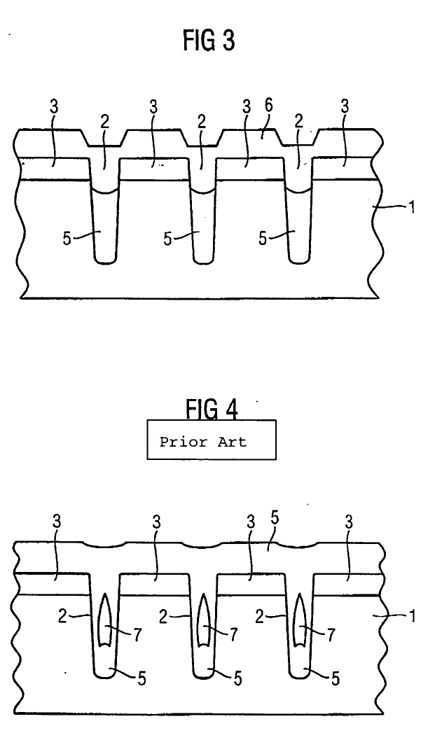

Then, as illustrated in FIG. 3, preferably an HDP oxide deposition layer 6 is produced by deposition of silicon oxide by means of an HDP process (“High Density Plasma” process) in the same process tool in order to form a so-called HDP cap over the entire insulation structure, i.e. by plasma-induced vapor deposition of silicon oxide from silane and oxygen at, for example, 400° C.

The HDP oxide deposition layer 6 or the HDP cap is then advantageously polished back to the nitride by means of a chemical mechanical polishing process (CMP process).

Then, the nitride mask 3 can either be used for further process steps or likewise removed by means of a chemical mechanical polishing process, in which case the oxide filling is likewise planarized down to the substrate surface.

1. Method for fabricating a trench isolation structure, comprising the following steps:
Forming a mask (3) on a substrate (1);
Forming at least one trench (2) in the substrate (1) by means of the mask (3);
Carrying out selective deposition of a first insulation material (5) to at least partially fill the at least one trench (2) in the substrate (1) with the insulation material (5) in the presence of the mask (3); and
applying a second insulation material (6) over the entire surface of the structure in order to fill the at least one trench (2) in the substrate (1) at least up to the top side of the mask (3).

2. Method for fabricating a trench isolation structure according to claim 1, characterized in that the substrate (1) is made from silicon, the mask is made from silicon nitride and the first and second insulation materials (5, 6) are formed from silicon oxide.

3. Method for fabricating a trench isolation structure according to claim 1, characterized in that following the selective deposition a conditioning step is carried out in order to compact the first insulation material (5).

4. Method for fabricating a trench isolation structure according to claim 1 characterized in that the second insulation material (6) is applied by means of an HDP process (“High Density Plasma” process), preferably in the same process tool.

5. Method for fabricating a trench isolation structure according to claim 1, characterized in that the second insulation material (6) is planarized by chemical mechanical polishing (CMP) on the mask (3).
